(19) United States
(12) Patent Application Publication
(10) Pub. No.: US 2015/0136170 A1
(43) Pub. Date: May 21, 2015

(54) METHOD FOR REMOVING ADHESIVE AGENT

(71) Applicant: HON HAI PRECISION INDUSTRY CO., LTD., New Taipei (TW)

(72) Inventors: MING-JEN CHANG, New Taipei (TW); JHIH-KUEI GE, New Taipei (TW); CHANG-CHIN WU, New Taipei (TW)

(21) Appl. No.: 14/520,910

(22) Filed: Oct. 22, 2014

(30) Foreign Application Priority Data
Nov. 19, 2013 (TW) 102142012

(51) Int. Cl. B08B 3/08; H05K 3/22; B08B 1/00

(52) U.S. Cl. CPC B08B 3/08; B08B 1/00; H05K 3/22
USPC 134/1; 134/6

(57) ABSTRACT

A method for removing an adhesive agent from a base plate with a plurality of accessories installed adjacent to the adhesive agent includes certain steps. The steps form a protection layer on the base plate, and the protection layer completely covers the electronic members and completely or partially covers the adhesive agent. The protection layer is solidified and a part of the protection layer is removed to expose the adhesive agent. The base plate is soaked in a removing solution to soften the adhesive agent and decrease an adhering strength of the adhesive agent, the protection layer being resistant to the removing solution to protect the electronic members. The softened adhesive agent is scraped off and the remaining protection layer removed.

### FIELD

The subject matter herein generally relates to a method for adhesive removal.

### BACKGROUND

Adhesives are used for adhering two workpieces together. Usually, a high adhesive strength is employed for strongly adhering the two workpieces.

### BRIEF DESCRIPTION OF THE DRAWINGS

Implementations of the present technology will now be described, by way of example only, with reference to the attached figures.

FIG. 1 is a flowchart of an embodiment of a method for removing an adhesive agent.

FIGS. 2 to 7 illustrate a process for removing an adhesive agent from an electronic device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

A method for removing an adhesive agent from a base plate with a plurality of accessories installed adjacent to the adhesive agent can include the following procedures. A protection layer can be formed on the base plate to completely cover the plurality of accessories and completely or partially cover the adhesive agent. The protection layer can be solidified. A part of protection layer can be removed to expose the adhesive agent. The base plate can be soaked in a removing solution to soften the adhesive agent and to decrease an adhesive strength of the adhesive agent, and the protection layer can be resistant to the removing solution to protect the accessories. The softened adhesive agent can be scraped off. The remaining protection layer can be removed.

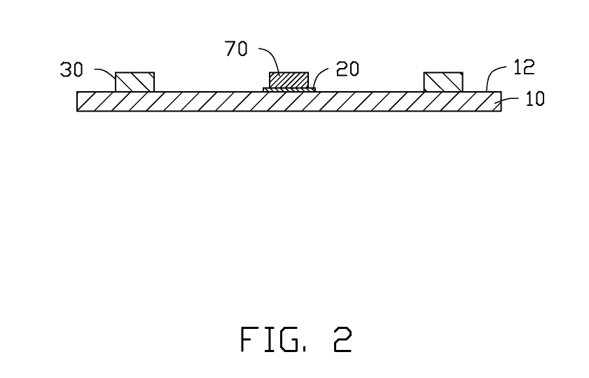

FIG. 2 illustrates an embodiment of an electronic device (not shown) which can include a base plate 10, a plurality of accessories 30, and an electronic element 70. The base plate 10 can have a top surface 12. The electronic element 70 and the accessories 30 can be installed on the top surface 12 of the base plate 10. The accessories 30 can be positioned adjacent to the electronic element 70. An adhesive agent 20 can be coated onto the top surface 12 around a periphery of the electronic element 70, the adhesive agent 20 being able to permeate into a space between the electronic element 70 and the base plate 10, so that the electronic element 70 and the base plate 10 can be adhered together after curing the adhesive agent 20, and the electronic element 70 can be electrically coupled to the base plate 10. The adhesive agent 20 can be made of epoxy resins. The adhesive agent 20 can have a strong adhering strength and be solidified in a temperature range from 0 to 180 degrees Celsius. In at least one embodiment, the base plate 10 can be a printed circuit board, the electronic element 70 can be a chip. When the connection of the electronic element 70 and the base plate 10 is bad, the electronic element 70 can be removed to expose the adhesive agent 20, and the adhesive agent 20 can be removed, and then the electronic element 70 can be electrically reconnected to the base plate 10.

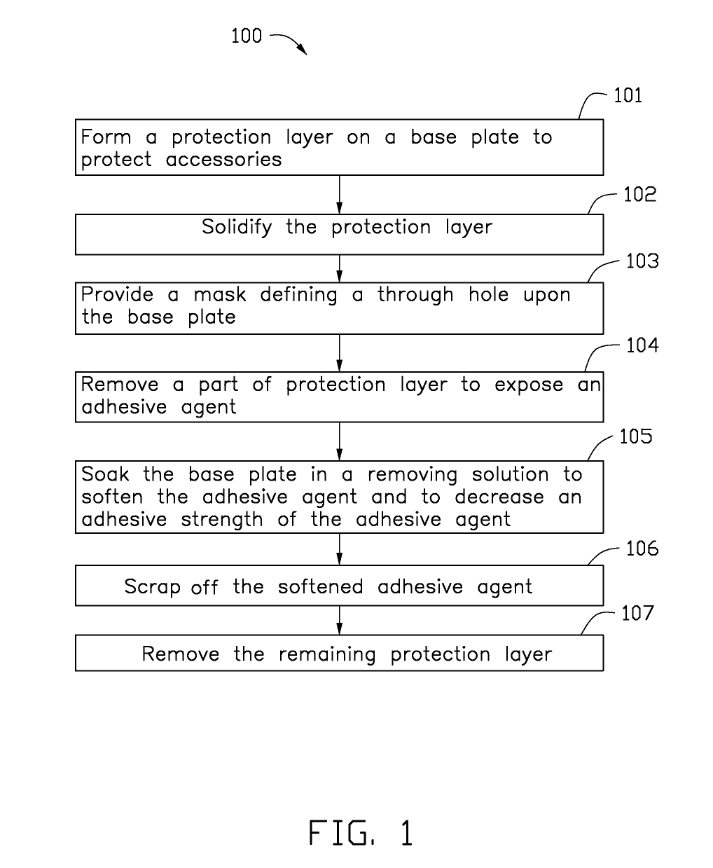

FIG. 1 illustrates a flowchart in accordance with an example embodiment. The example method 100 for removing the adhesive agent from the base plate is provided by way of example, as there are a variety of ways to carry out the method. The method 100 described below can be carried out using the configurations illustrated in FIGS. 2 to 7, for example, and various elements of these figures are referenced in explaining example method 100. Each block shown in FIG. 1 represents one or more processes, methods, or subroutines, carried out in the example method 100. Additionally, the illustrated order of blocks is by example only and the order of the blocks can change. The example method 100 for removing the adhesive agent from the base plate can begin at block 101.

At block 101, a protection layer is formed on the base plate and completely covers the accessories to protect the base plate and the accessories from damage.

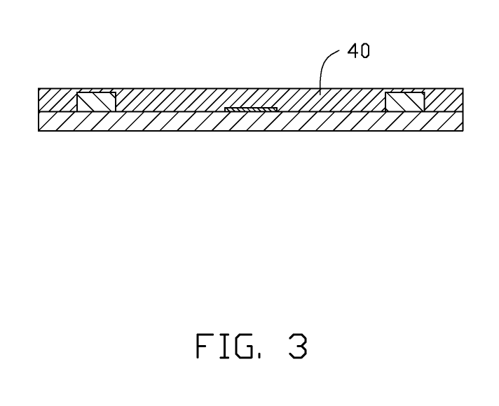

FIGS. 2 and 3 illustrate the protection layer 40 being formed on the top surface 12 of the base plate 10, and completely covering the top surface 12, the accessories 30, and the adhesive agent 20. In at least one embodiment, the protection layer 40 can partially cover the adhesive agent, so long as the protection layer 40 can protect the accessories 30 from damage. The protection layer 40 can have an excellent corrosion resistance, so that the protection layer 40 can protect the base plate 10 and the accessories 30 from corrosion causing by a chemical reagent, such as removing solutions. In at least one embodiment, the protection layer 40 can be made of silicone resin or fluorine resin. The protection layer 40 can be formed by methods well known in the art, such as an inkjet printing method, or a magnetron sputtering method.

At block 102, the protection layer is solidified. In at least one embodiment, the protection layer can be solidified by one or more methods selected from the group consisting of room temperature curing, high temperature curing, and ultraviolet curing, provided that the protection layer can be solidified.

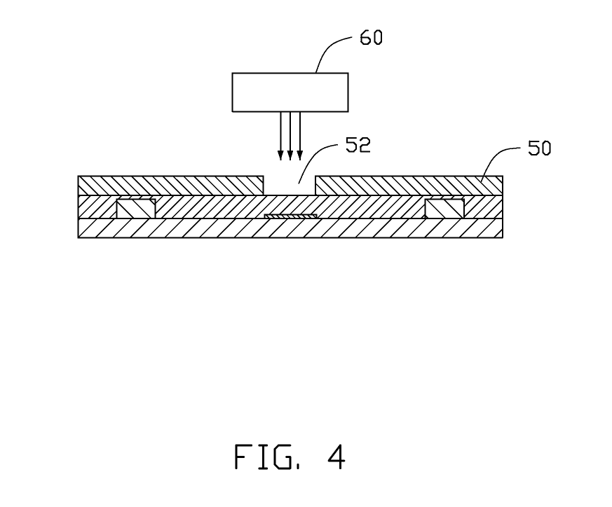

At block 103, a mask defining a through hole with a shape matching that of the adhesive agent is provided. FIG. 4 illustrates that the mask 50 can define the through hole 52 which matches the shape of the adhesive agent, and can be positioned upon the base plate.

At block 104, a part of protection layer which corresponds to the adhesive agent is removed by a laser control system to expose the adhesive agent.

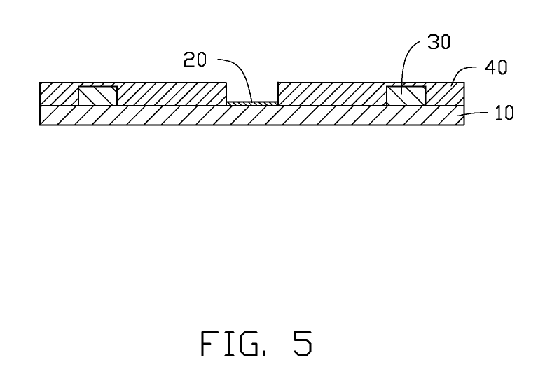

FIGS. 4 and 5 illustrate that a plurality of laser beams emitted from the laser control system 60 can be directed on the parts of protection layer 40 exposed via the through hole 52. When a power density of the laser beams is more than a threshold power density of the protection layer 40, the protection layer 40 can be vaporized by the laser beams. In this way, parts of the adhesive agent 20 can be exposed.

At block 105, the base plate soaks in a removing solution with a predetermined temperature for a predetermined length of time to soften the adhesive agent and to decrease an adhesive strength of the adhesive agent. The removing solution can swell the cured adhesive agent to soften the adhesive agent so that the adhesive strength of the adhesive agent can be decreased. A material of the removing solution can depend on the material of the adhesive agent. For example, the removing solution can be made of one or more materials selected from the group consisting of aromatics, esters, ketones, alcohol-ethers, sulfoxides, and amides, so long as the removing solution can soften the adhesive agent. In at least one embodiment, the removing solution can be made of one or more materials selected from the group consisting of alcohol-ethers, sulfoxides, and amides. In at least one embodiment, a soaking temperature of the adhesive agent can be in a range from 100 to 120 degrees Celsius. A soaking time of the adhesive agent can be in a range from 60 to 120 minutes.

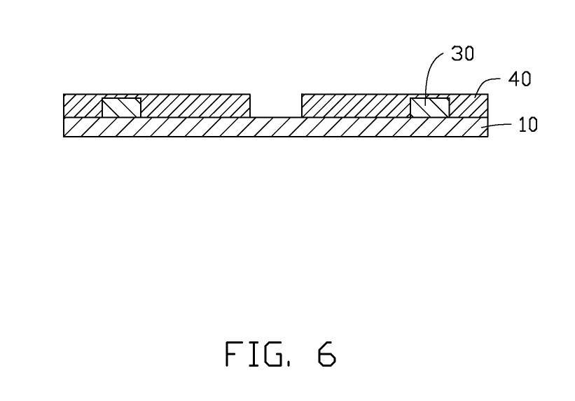

At block 106, the softened adhesive agent is scraped off. FIGS. 5 and 6 illustrate that the softened adhesive agent 20 is scraped off to expose a part of the base plate 10.

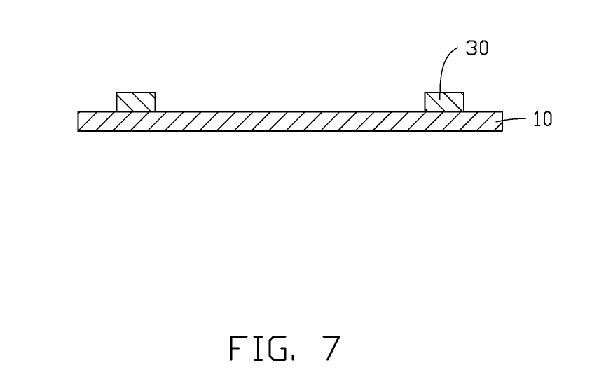

At block 107, the remaining protection layer is removed. FIGS. 6 and 7 illustrate that the remaining protection layer 40 can be removed to expose the accessories 30 and the base plate 10. The remaining protection layer 40 can be removed by methods such as a method of tearing, a method of dissolving, and a method employing high pressure equipment.

In at least one embodiment, when removing the part of the protection layer 40 which is located upon the adhesive agent 20, the mask 50 can be omitted, and the laser beams can be directly focused on the part of the protection layer 40 which is to be removed.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure, as defined by the appended claims.

What is claimed is:

1. A method for removing an adhesive agent from a base plate with at least one accessory installed adjacent to the adhesive agent, the method comprising:
forming a protection layer on the base plate to completely cover the at least one accessory and completely or partially cover the adhesive agent;
solidifying the protection layer;
removing a part of the protection layer to expose the adhesive agent;
soaking the base plate in a removing solution to soften the adhesive agent and to decrease an adhesive strength of the adhesive agent, the protection layer being resistant to the removing solution to protect the at least one accessory;
scraping off the softened adhesive agent; and
removing the remaining protection layer.

2. The method of claim 1, wherein the protection layer is made of silicone resin or fluorine resin.

3. The method of claim 1, wherein the removing solution can be made of one or more materials selected from the group consisting of aromatics, esters, ketones, alcohol-ethers, sulfoxides, and amides.

4. The method of claim 1, wherein the base plate is soaked in the removing solution with a predetermined temperature for a predetermined length of time.

5. The method of claim 4, wherein a soaking temperature is in a range from 100 to 120 degrees Celsius, and a soaking time is in a range from 60 to 120 minutes.

6. The method of claim 1, wherein the remaining protection layer is removed by a method of tearing, a method of dissolving, or a method employing high pressure equipment.

7. The method of claim 1, wherein the part of protection layer is removed by a laser control system.

8. The method of claim 7, wherein before removing the part of protection layer, a mask defining a through hole with a shape matching that of the adhesive agent is provided, and a plurality of laser beams emitted from the laser control system is directed on the part of protection layer exposed via the through hole to expose the adhesive agent.

9. The method of claim 1, wherein the protection layer is solidified by a method of room temperature curing, a method of high temperature curing, or a method of ultraviolet curing.
